(19) United States
(12) Patent Application Publication
(10) Pub. No.: US 2022/0326113 A1
(43) Pub. Date: Oct. 13, 2022

(54) Probe for Optical Circuit Inspection

(71) Applicant: Nippon Telegraph and Telephone Corporation, Tokyo (JP)

(72) Inventors: Toru Miura, Tokyo (JP); Yujiro Tanaka, Tokyo (JP); Hiroshi Fukuda, Tokyo (JP)

(21) Appl. No.: 17/615,996

(22) PCT Filed: Jun. 7, 2019
(86) PCT No.: PCT/JP2019/022706

§ 371 Date: Dec. 2, 2021

(51) Int. Cl. G01M 11/00; B06B 1/06

(52) U.S. Cl. CPC G01M 11/30; B06B 1/0655; H01L 41/1876

(57) ABSTRACT

An optical circuit inspection probe includes a piezoelectric element and a gel-like medium layer provided at an end of the piezoelectric element to absorb light and convert the light into a sound wave. The piezoelectric element may be formed of piezoelectric ceramics such as Pb (Zr·Ti)O₃ (PZT). The piezoelectric element has, for example, a cylindrical shape. The medium layer is formed of a hydrogel. The hydrogel may include, for example, polydimethylsiloxane (PDMS). Further, the medium layer may contain carbon.

### CROSS-REFERENCE TO RELATED APPLICATIONS

This application is a national phase entry of PCT Application No. PCT/JP2019/022706, filed on Jun. 7, 2019, which application is hereby incorporated herein by reference.

### TECHNICAL FIELD

The present invention relates to an optical circuit inspection probe used for inspection of an optical circuit.

### BACKGROUND

For the optical connection between a silicon optical circuit and an optical fiber, spot-size converters and lensed fibers have been used so far in order to improve the efficiency of the optical connection between a waveguide end face and the optical fiber. In recent years, with the progress of micromachining technology, there are many cases in which a grating including grooves with a width of several hundred nm is provided in a silicon waveguide to function as a grating coupler that radiates light upward and downward from an optical waveguide to a substrate surface, and is optically connected to an optical fiber.

For example, in silicon photonics, a technique using a grating coupler for optical connection with an optical fiber has been proposed (see Non Patent Literature 1). In this technique, the angle at which light emitted from the grating coupler to the upper surface satisfies the equation (1) described on page 7870 of Non Patent Literature 1, and is set to an inclination angle within 20 deg. from the direction perpendicular to the substrate. In this way, by using the grating coupler, light can be input and output in a direction substantially perpendicular to the substrate, so that basic functions can be inspected without cutting out a wafer into chips.

When the light is coupled to the grating coupler, a single mode fiber (SMF), a fiber array, or the like is used. Hereinafter, SMF 303 is described as an example with reference to FIG. 7. In this example, a grating coupler 302 is provided on an optical waveguide 301 formed on a substrate 300. In order to optically couple the SMF 303 and the grating coupler 302, alignment in a plane (XY plane) parallel to a plane of the substrate 300, alignment in angular directions Ox, Oy, and Oz determined by parameters such as a grating period (pitch), and alignment at a distance Z between the grating coupler 302 and the SMF 303 are required. If any one of these axes is deviated, optical coupling between the two cannot be performed, making alignment difficult.

In order to perform this alignment, generally, first, a sample circuit for alignment (optical circuit for alignment) is prepared, and alignment is performed using the prepared sample circuit. Next, an optical fiber is moved to a desired optical circuit by using a stepping motor or the like so that the optical fiber and the sample circuit are in a relative positional relationship set by alignment, and the optical fiber and the optical circuit are optically connected in this state. In this state, for example, a predetermined measurement in an optical circuit is performed.

### CITATION LIST

Non Patent Literature

Non Patent Literature 1: C. Li. et al., “CMOS-compatible High Efficiency Double-etched Apodized Waveguide Grating Coupler”, Optics Express, vol. 21, no. 7, pp. 7868-7874, 2013.

### SUMMARY

### Technical Problem

In an inspection of an optical circuit when a conventional grating coupler is used for input and output, as illustrated in FIG. 6, first, light is incident on an optical circuit 304 to be inspected from an input SMF 303 via an input grating coupler 302a and an optical waveguide 301. Further, the transmitted light is received by an output SMF 305 via an output grating coupler 302b, and the desired characteristics are evaluated. As described above, these alignments are required for optical coupling between the optical fiber and the grating coupler. Therefore, in the measurement of this type of optical circuit, the time required for the alignment determines inspection throughput.

Embodiments of the present invention have been made to solve the above-described problem, and an object thereof is to carry out an inspection of an optical circuit more quickly.

### Means for Solving the Problem

The optical circuit inspection probe according to embodiments of the present invention includes a piezoelectric element and a gel-like medium layer provided at an end of the piezoelectric element to absorb light and convert the light into a sound wave.

In the optical circuit inspection probe, the medium layer is formed of a hydrogel.

In the optical circuit inspection probe, the medium layer is formed of polydimethylsiloxane.

In the optical circuit inspection probe, the medium layer contains carbon.

In the optical circuit inspection probe, the piezoelectric element is formed of piezoelectric ceramics.

### Effects of embodiments of the Invention

As described above, according to embodiments of the present invention, since the gel-like medium layer that absorbs light and converts it into a sound wave is provided at the end of the piezoelectric element to form an optical circuit inspection probe, the inspection of an optical circuit can be performed more quickly.

### BRIEF DESCRIPTION OF THE DRAWINGS

FIG. 1 is a perspective view illustrating a configuration of an optical circuit inspection probe according to an embodiment of the present invention.

FIG. 2 is a characteristic graph illustrating a result of measuring light intensity dependence of the sound wave generated in a medium layer 102.

FIG. 3A is a perspective view illustrating Measurement Example 1 in which the optical circuit inspection probe according to an embodiment of the present invention is used.

FIG. 3B is a perspective view illustrating Measurement Example 1 in which the optical circuit inspection probe according to an embodiment of the present invention is used.

FIG. 4 is a perspective view illustrating Measurement Example 2 in which the optical circuit inspection probe according to an embodiment of the present invention is used.

FIG. 5 is a perspective view illustrating an aligned state of the SMF 303 with respect to the grating coupler 302.

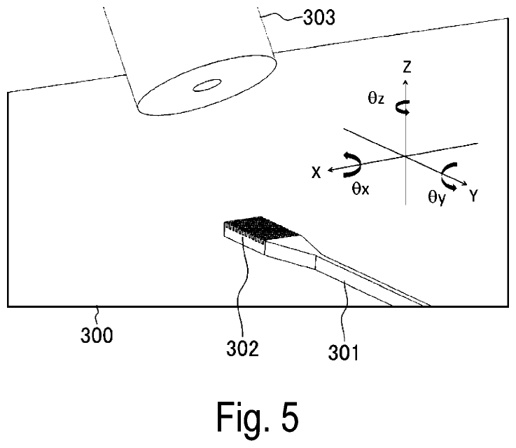

FIG. 6 is an explanatory view illustrating the inspection of the optical circuit 304.

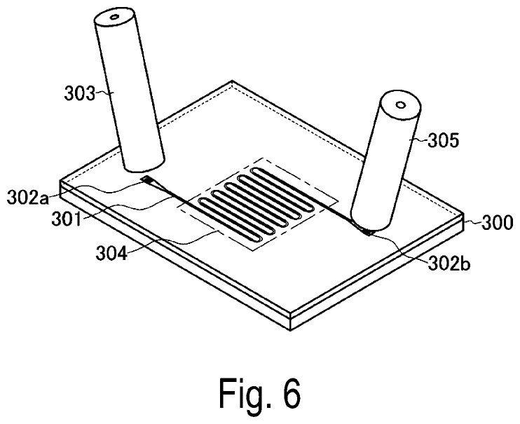

### DETAILED DESCRIPTION OF ILLUSTRATIVE EMBODIMENTS

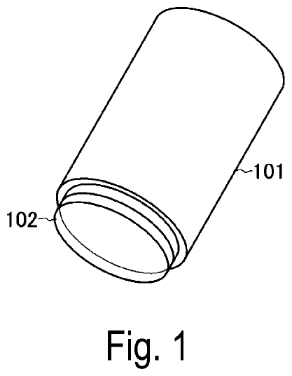

Hereinafter, an optical circuit inspection probe according to an embodiment of the present invention will be described with reference to FIG. 1. The optical circuit inspection probe includes a piezoelectric element 101 and a gel-like medium layer 102 provided at an end of the piezoelectric element 101 to absorb light and convert the light into a sound wave. The piezoelectric elements 101 may be formed of piezoelectric ceramics such as Pb (Zr·Ti)O₃ (PZT). The piezoelectric element 101 has, for example, a cylindrical shape.

The medium layer 102 is formed of a hydrogel. The hydrogel may include, for example, polydimethylsiloxane (PDMS). Further, the medium layer 102 may contain carbon. By containing carbon, the efficiency of light absorption of the medium layer 102 can be improved.

The optical circuit inspection probe according to the embodiment uses the photoacoustic effect to convert the light received by the medium layer 102 into a sound wave and converts the sound wave obtained by the conversion into an electric signal by the piezoelectric element 101. The photoacoustic method is a phenomenon in which molecules that have absorbed light energy release heat, and sound is generated by volume expansion due to this heat. There are many examples of using water as a medium for absorbing light, but when water is used, the usage and applications of the probe are limited.

On the other hand, the medium layer 102 formed of a hydrogel that absorbs light in a wavelength band propagated as signal light to an optical circuit absorbs light and generates a sound wave. The medium layer 102 is integrated on the piezoelectric element 101 and used as an optical circuit inspection probe by optical-sonic conversion. When the optical circuit inspection probe configured in this way is used, the light passing in the optical circuit to be inspected can be converted into a sound wave for measurement by bringing the medium layer 102 integrated in the piezoelectric element 101 into close contact with a place where light is to be detected.

Further, if the size of the measurement surface of the piezoelectric element 101 is made larger than the end surface of an optical fiber, the accuracy of alignment may be coarser than that when the optical fiber is used, and the width of the measurement surface of the piezoelectric element 101 only needs to cover the light emitting position, whereby the time and operation required for alignment can be reduced.

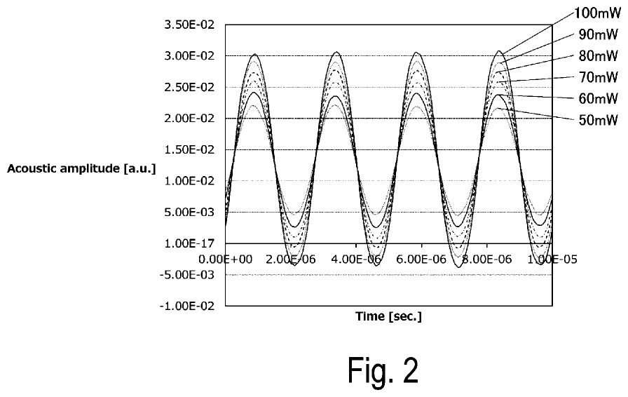

Next, FIG. 2 illustrates the results of measuring the light intensity dependence of the sound wave generated in the medium layer 102 including PDMS containing carbon. It can be seen that when the intensity of the emitted light of a light source (the intensity of the incident light on the optical circuit inspection probe) is changed, the intensity of the measured sound wave is also changed. As described above, since the intensity of the measured sound wave changes according to the intensity of light incident on the medium layer 102, the intensity of the light can be measured and insertion loss of the optical circuit can be measured.

Hereinafter, specific measurement using the above-mentioned principle will be described.

Measurement Example 1

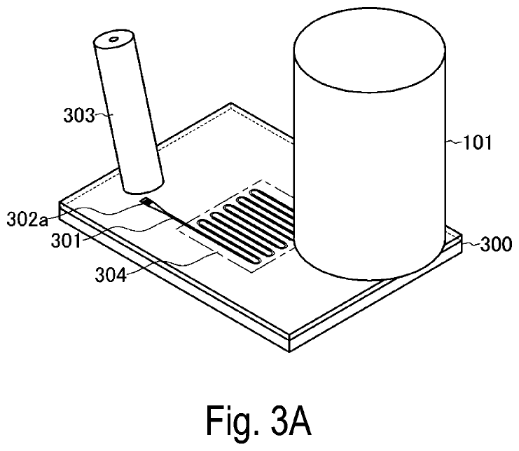

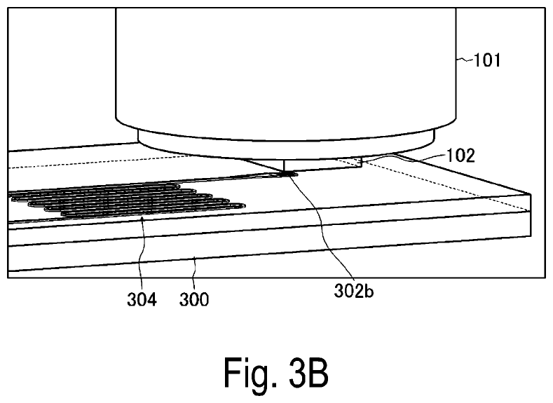

First, Measurement Example 1 will be described with reference to FIGS. 3A and 3B. Light emitted from a single mode fiber (SMF) 303 and incident through an input grating coupler 302a enters an optical circuit 304 to be inspected via an optical waveguide 301 to be inspected formed on a substrate 300. In this way, the light incident on the optical waveguide 301 and emitted from the optical waveguide 301 is emitted from the output grating coupler 302b. The emitted light is received by the medium layer 102 and photoacoustic-converted, and the sound wave obtained by the conversion is converted into an electric signal by the piezoelectric element 101 for measurement. Based on this measurement result, the optical circuit 304 can be evaluated.

In this example, the optical circuit 304 is formed of an optical waveguide, and transmitted light of the optical waveguide can be converted into a sound wave and detected by the optical circuit inspection probe according to the embodiment, and the intensity of the detected measured value depends on the intensity of the transmitted light of the optical waveguide. Therefore, the propagation loss per unit length can be derived from the measurement of the transmitted light intensity of optical waveguides having different lengths. In this example, a grating coupler is used for incidence of light, and if the grating coupler is formed, measurement can be performed in the state of a wafer or chip. If a wafer is cut out into chips and an edge coupler is formed at the ends of the chips, light can be incident on the optical circuit inspection probe according to the embodiment from the edge coupler.

Further, the medium layer 102 may be present in a region where light is emitted. For example, as illustrated in FIG. 3B, by arranging the medium layer 102 only on the upper surface of the output grating coupler 302b, generation of sound waves at unnecessary places can be avoided. In this example, the propagation loss is evaluated by measuring the light intensity, but other items can be evaluated as long as the evaluation can be performed by measuring the light intensity in the inspection. For example, it is possible to measure the extinction ratio and modulation efficiency of the light intensity of an optical modulator.

Measurement Example 2

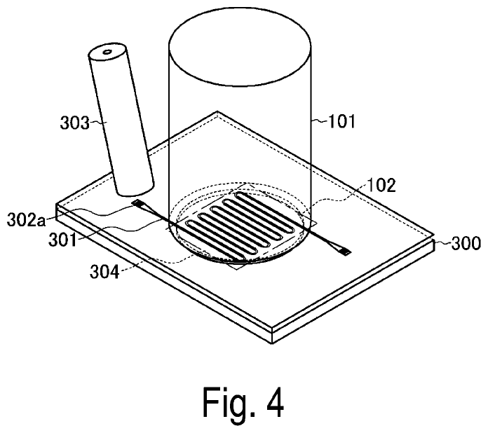

Next, Measurement Example 2 will be described with reference to FIG. 4. In the inspection of the optical circuit by the above-mentioned optical circuit inspection probe, if the light from the optical circuit to be inspected is converted into a sound wave by the medium layer 102, the light can be measured by the medium layer 102. Therefore, as described in Measurement Example 1, it may not be necessary to use the light emitted from the grating coupler. For example, when the cause of the waveguide loss in the optical circuit is the roughness of the wall surface of the optical waveguide constituting the optical circuit, or the scattering caused by the existence of discontinuities or reflection points of the optical waveguide, the scattered light can be measured by the optical circuit inspection probe according to the embodiment.

Light emitted from the single mode fiber (SMF) 303 and incident through the input grating coupler 302a enters the optical circuit 304 to be inspected via the optical waveguide 301 to be inspected that is formed on the substrate 300. If the light is incident on the optical waveguide 301 and scattered light is generated from the optical circuit 304 formed of, for example, a long optical waveguide, the medium layer 102 is brought into close contact with the entire area of the optical circuit 304. In this way, the intensity of the sound wave measured by the optical circuit inspection probe according to the embodiment is the intensity of scattered light, and indicates the magnitude of the waveguide loss in the optical circuit 304.

As illustrated in Measurement Example 1, the propagation loss can be measured by measuring the scattered light intensity of optical circuits having different lengths of optical waveguides. It is also possible to apply this measurement to lot inspection by measuring at the same location for each wafer and checking for abnormal scattering. The advantage of this inspection is that the inspection can be performed on an optical circuit at an arbitrary location on the wafer without using a grating coupler that emits light toward the upper surface. Since it is not necessary to emit light from a grating coupler or the like for inspection, it is possible to inspect not only the inspection circuit but also an actual device.

As described above, according to embodiments of the present invention, since a gel-like medium layer that absorbs light and converts it into a sound wave is provided at the end of a piezoelectric element to serve as an optical circuit inspection probe, the inspection of an optical circuit can be performed more quickly.

Embodiments of the present invention facilitate, for example, the alignment in the measurement of the light intensity emitted from the output grating coupler of the optical circuit. By converting light into a sound wave and receiving the sound wave obtained by the conversion with a piezoelectric element having a large receiving surface, the accuracy required for alignment is relaxed. As a result, the time required for alignment can be shortened, and if it can be used for an inspection at the time of manufacturing, the inspection cost can be reduced. In addition, the presence or absence of abnormal scattering from the optical circuit can be examined at any location. As a result, since the circuit does not have to be an inspection circuit, and evaluation can be performed on an actual device, and the actual device can be evaluated directly, which has an advantage of increasing the accuracy of the inspection, compared to evaluating the characteristics of the device from an inspection of a peripheral inspection circuit.

The present disclosure is not limited to the embodiments described above, and it is obvious that many modifications and combinations can be implemented by a person having ordinary knowledge in the field within the technical spirit of the present disclosure.

### REFERENCE SIGNS LIST

101 piezoelectric element

102 medium layer.

1-5. (canceled)

6. An optical circuit inspection probe, comprising:
a piezoelectric element; and
a gel-like medium layer at an end of the piezoelectric element and configured to:
absorb light; and
convert the light into a sound wave.

7. The optical circuit inspection probe according to claim 6, wherein the gel-like medium layer is formed of a hydrogel.

8. The optical circuit inspection probe according to claim 7, wherein the gel-like medium layer is formed of polydimethylsiloxane.

9. The optical circuit inspection probe according to claim 8, wherein the gel-like medium layer contains carbon.

10. The optical circuit inspection probe according to claim 6, wherein the piezoelectric element comprises a piezoelectric ceramic.

11. An optical circuit inspection probe, comprising:
a piezoelectric element; and
a medium layer at an end of the piezoelectric element and configured to:
absorb light; and
convert the light into a sound wave, wherein the medium layer is formed of a hydrogel.

12. The optical circuit inspection probe according to claim 11, wherein the hydrogel is polydimethylsiloxane (PDMS).

13. The optical circuit inspection probe according to claim 11, wherein the piezoelectric element comprises a piezoelectric ceramic.

14. The optical circuit inspection probe according to claim 13, wherein the piezoelectric ceramic is Pb (Zr·Ti)O₃ (PZT).

15. The optical circuit inspection probe according to claim 11, wherein the medium layer further comprises carbon.

16. The optical circuit inspection probe according to claim 11, wherein the piezoelectric element has a cylindrical shape.

17. A method of operating a optical circuit inspection probe, the method comprising:
absorbing, by a medium layer, light, wherein the medium layer is disposed at an end of a piezoelectric element; and
converting, by the medium layer, the light into a sound wave, wherein the medium layer is formed of a hydrogel.

18. The method according to claim 17, wherein the hydrogel is polydimethylsiloxane (PDMS).

19. The method according to claim 17, wherein the piezoelectric element comprises a piezoelectric ceramic.

20. The method according to claim 19, wherein the piezoelectric ceramic is Pb (Zr·Ti)O₃ (PZT).

21. The method according to claim 17, wherein the medium layer further comprises carbon.
